(19) United States
(12) Patent Application Publication
(10) Pub. No.: US 2016/0218318 A1
(43) Pub. Date: Jul. 28, 2016

(54) ORGANIC LIGHT EMITTING DIODE DISPLAY

(71) Applicant: Samsung Display Co., Ltd., Yongin-si (KR)

(72) Inventors: Yun-Mo Chung, Yongin-si (KR); Ho Jin Yoon, Yongin-si (KR); Dae Woo Lee, Yongin-si (KR); Jae Beom Choi, Yongin-si (KR)

(21) Appl. No.: 14/963,613

(22) Filed: Dec. 9, 2015

(30) Foreign Application Priority Data
Jan. 28, 2015 (KR) 10-2015-0013813

(51) Int. Cl. H01L 51/52; H01L 51/56; H01L 27/32

(52) U.S. Cl. CPC H01L 51/5246; H01L 27/3246; H01L 51/5259; H01L 51/56; H01L 51/5256

(57) ABSTRACT

An organic light emitting diode display includes: a substrate including a display area displaying an image and a non-display area positioned around the display area; a first electrode formed in the display area connected with a thin film transistor; a pixel defining layer formed on the first electrode thereby defining a pixel area; an organic emission layer formed on the first electrode contacting the first electrode in the pixel area; a second electrode formed on the pixel defining layer contacting the organic emission layer; a passivation layer formed on the second electrode and the pixel defining layer; a filler covering the passivation layer in the display area; and a getter formed in the non-display area on the substrate and surrounding the display area, in which the passivation layer overlaps with the getter.

### CROSS-REFERENCE TO RELATED APPLICATION

This application claims priority to and the benefit of Korean Patent Application No. 10-2015-0013813 filed in the Korean Intellectual Property Office on Jan. 28, 2015, the entire contents of which are incorporated herein by reference.

### BACKGROUND

1. Field

The present disclosure relates to an organic light emitting diode display.

2. Description of the Related Technology

Display devices include a liquid crystal display (LCD), a plasma display panel (PDP), an organic light emitting diode device (OLED), a field effect display (FED), an electrophoretic display device, and the like.

The OLED device includes two electrodes and an organic emission layer positioned therebetween, and an electron injected from one electrode and a hole injected from the other electrode are coupled with each other in the organic emission layer to generate an exciton, and the exciton emits energy to emit light.

Since the OLED has a self-luminance characteristic and does not require a separate light source as does the LCD, a thickness and a weight thereof may be relatively reduced. Further, since the OLED has high-grade characteristics such as low power consumption, high luminance, and a high response speed, the OLED receives attention as a next-generation display device.

In the OLED, a filler is positioned on a pixel defining layer, and in a partial area, the pixel defining layer and the filler may directly contact each other.

In this case, there may be a problem in that the organic emission layer deteriorates by a product material due to reaction between two materials through the contact between the pixel defining layer and the filler or organic components of the filler.

The above information disclosed in this Background section is only for enhancement of understanding of the background of the invention and therefore it may contain information that does not form the prior art that is already known in this country to a person of ordinary skill in the art.

### SUMMARY OF CERTAIN INVENTIVE ASPECTS

The present disclosure has been made in an effort to provide an organic light emitting diode display preventing an organic emission layer from deteriorating due to organic components of a filler which penetrates into a pixel defining layer.

One embodiment provides an organic light emitting diode display including: a substrate including a display area displaying an image and a non-display area positioned around the display area; a first electrode formed in the display area connected with a thin film transistor; a pixel defining layer formed on the first electrode thereby defining a pixel area; an organic emission layer formed on the first electrode contacting the first electrode in the pixel area; a second electrode formed on the pixel defining layer contacting the organic emission layer; a passivation layer formed on the second electrode and the pixel defining layer; a filler covering the passivation layer in the display area; and a getter formed in the non-display area on the substrate and surrounding the display area, in which the passivation layer overlaps with at least a part of the getter.

The passivation layer may contact the second electrode and the pixel defining layer.

The passivation layer may include an organic material.

The passivation layer may include an inorganic material.

The inorganic material may be silicon nitride (SiNx) or silicon oxide (SiOx).

The passivation layer may be configured by a plurality of layers.

The filler may include at least one of epoxy, epoxy acrylate, polyimide, or silicon.

The thin film transistor may include an active layer formed on the substrate, a gate electrode formed on the active layer, and source and drain electrodes positioned on the gate electrode and connected with the active layer.

The organic light emitting diode display may further include an encapsulation part surrounding the getter in the non-display area.

The passivation layer may overlap with a part of the encapsulation part.

The passivation layer may include an inorganic material.

The inorganic material may include at least one of silicon nitride (SiNx) or silicon oxide (SiOx).

The organic light emitting diode display may further include an encapsulation substrate disposed to face the substrate on filler and contacting the encapsulation part.

A method of manufacturing the organic light emitting diode display may include: providing a substrate including a display area displaying an image and a non-display area positioned around the display area; forming a first electrode in the display area on the substrate and connected with a thin film transistor; forming a pixel defining layer on the first electrode thereby defining a pixel area; forming an organic emission layer on the first electrode and contacting the first electrode in the pixel area; forming a second electrode on the pixel defining layer and contacting the organic emission layer; forming a passivation layer on the second electrode and the pixel defining layer; covering the passivation layer in the display area by a filler; and forming a getter in the non-display area on the substrate and surrounding the display area, wherein the passivation layer overlaps with the getter.

According to one or more embodiments, the passivation layer may cover both the pixel defining layer and the common electrode to prevent contact between the filler and the pixel defining layer, and as a result, it, may be possible to prevent the organic emission layer from deteriorating due to the organic components of the filler.

Further, it may be possible to prevent reduction in pixels by preventing the organic emission layer from deteriorating.

### BRIEF DESCRIPTION OF THE DRAWINGS

FIG. 1 is a plan view of an organic light emitting diode display according to an embodiment.

FIG. 2 is a cross-sectional view of the organic light emitting diode display according to the embodiment taken along line II-II of FIG. 1.

FIG. 3 is a cross-sectional view of the organic light emitting diode display according to the embodiment taken along line of FIG. 1.

FIG. 4 is a layout view of one pixel of the organic light emitting diode display.

### DETAILED DESCRIPTION OF CERTAIN INVENTIVE EMBODIMENTS

Hereinafter, certain embodiments will be described in detail with reference to the accompanying drawings. As those skilled in the art would realize, the described embodiments may be modified in various ways, without departing from the spirit or scope of the present invention. On the contrary, the embodiments introduced herein are provided to make disclosed contents thorough and complete and sufficiently transfer the spirit to those skilled in the art.

In the drawings, the thickness of layers, films, panels, regions, and the like may be exaggerated for clarity. It will be understood that when a layer is referred to as being “on” another layer or substrate, it can be directly on the other layer or substrate, or another layer or substrate intervening them may also be present. Like reference numerals generally designate like elements throughout the specification.

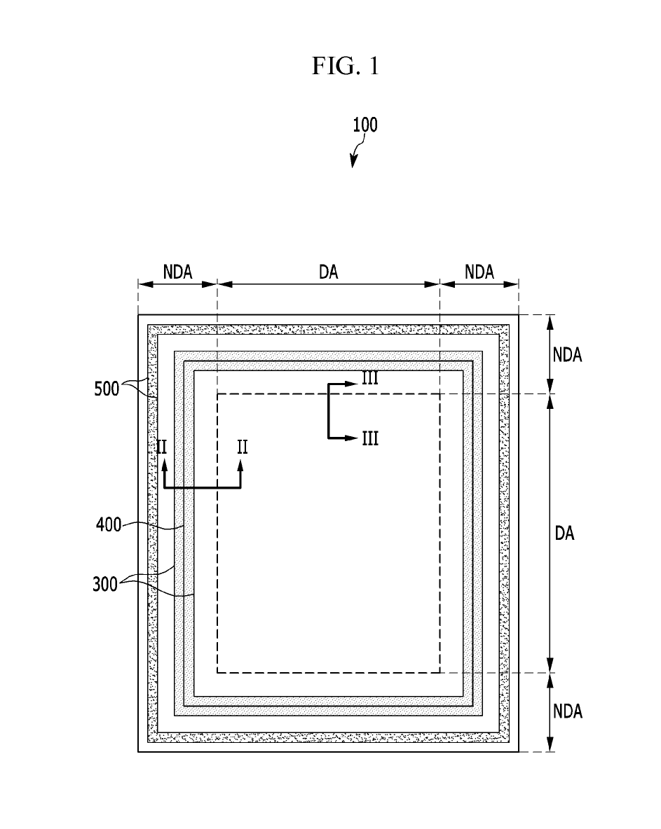

Hereinafter, an organic light emitting diode display according to an embodiment will be described with reference to FIGS. 1 to 4.

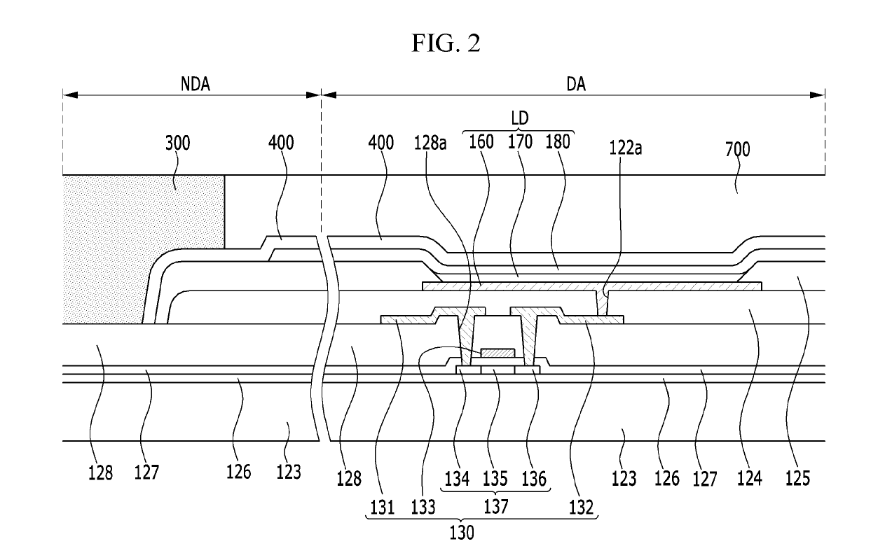

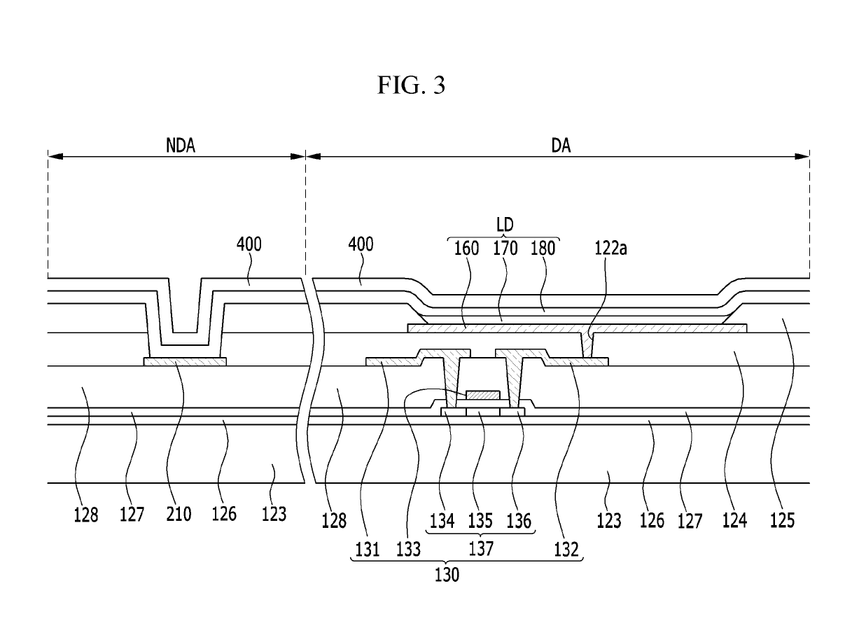

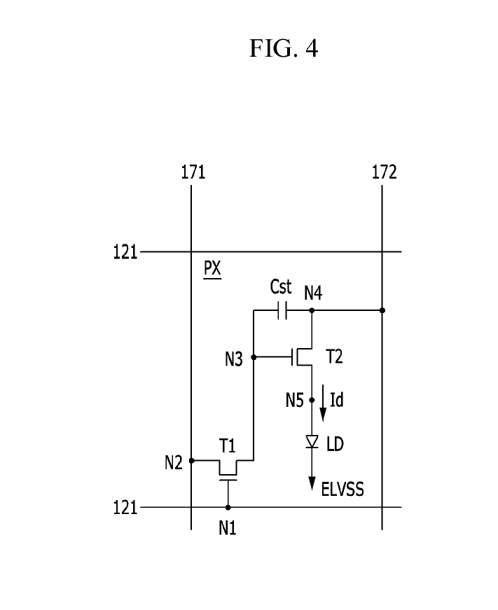

FIG. 1 is a plan view of an organic light emitting diode display according to an embodiment, FIG. 2 is a cross-sectional view of the organic light emitting diode display according to the embodiment taken along line II-II of FIG. 1, FIG. 3 is a cross-sectional view of the organic light emitting diode display according to the embodiment taken along line III-III of FIG. 1, and FIG. 4 is a layout view of one pixel of the organic light emitting diode display.

Referring to FIGS. 1 and 2, an organic light emitting diode display 100 according to the embodiment includes a display area DA displaying an image and a non-display area NDA positioned around the display area DA.

In the display area DA, an organic light emitting element, a thin film transistor (TFT) driving the organic light emitting element, and a plurality of wires connected to the organic light emitting element and the TFT may be formed. In addition, in the non-display area NDA, a wire extended from the display area DA, a pad part where a pad electrode is formed, and a getter 300, and an encapsulation part 500 may be formed. The configurations formed in the display area and the non-display area are described below.

Referring to FIG. 1, in the non-display area NDA, the encapsulation part 500 surrounding the display area DA is formed. The encapsulation part 500 is attached to a substrate 123 positioned below and an encapsulation substrate (not illustrated) facing the substrate 123, so as to encapsulate an internal space including the organic light emitting element. The encapsulation part 500 blocks moisture, oxygen, or the like to prevent the organic light emitting element from deteriorating by moisture, oxygen, or the like. The encapsulation part 500 may include frit or epoxy. However, the material of the encapsulation part 500 is not limited thereto, and the encapsulation part 500 may include various known materials used in the encapsulation part of the display device.

The getter 300 surrounding the display area DA may be formed inside the encapsulation part 500. The getter 300 absorbs moisture or oxygen penetrating through the encapsulation part 500 to prevent the moisture or oxygen from penetrating into the display area DA. Like the encapsulation part 500, the getter 300 may be attached onto the substrate 123 and the encapsulation substrate (not illustrated). Accordingly, between the substrate 123 and the encapsulation substrate (not illustrated), the display area DA where the organic light emitting element and the like are formed, the getter 300, and the encapsulation part 500 are sequentially disposed.

Referring to FIG. 2, a substrate 123 is formed as an insulation substrate including glass, quartz, ceramics, plastic, or the like.

In addition, a buffer layer 126 is formed on the substrate 123. The buffer layer 126 serves to prevent impure materials from penetrating and to planarize the surface. The buffer layer 126 may include various materials capable of performing the functions. For example, a silicon nitride (SiNₓ) layer, a silicon oxide (SiO₂) layer, or a silicon oxynitride (SiOₓN_{y}) layer may be used in the buffer layer 126. However, the buffer layer 126 is not a necessarily required configuration, and may be omitted according to a kind of substrate 123 and a process condition.

In the display area DA, a driving semiconductor layer 137 is formed on the buffer layer 126. The driving semiconductor layer 137 is formed as a polysilicon layer. Further, the driving semiconductor layer 137 includes a channel region 135 in which impurities are not doped, and a source region 134 and a drain region 136 in which the impurities are doped at both sides of the channel region 135. The doped ion materials may be P-type impurities such as, for example, boron (B), and B₂H₆ may be used. The impurities vary according to a kind of thin film transistor. Herein, a driving transistor including the driving semiconductor layer 137 is described, but is not limited thereto, and a switching transistor may also be formed on the buffer layer 126.

A gate insulating layer 127 including silicon nitride (SiNx) or silicon oxide (SiO₂) is formed on the driving semiconductor layer 137.

A gate line including a driving gate electrode 133 is formed on the gate insulating layer 127. The driving gate electrode 133 is formed to overlap with at least a part of the driving semiconductor layer 137, particularly, the channel region 135.

An interlayer insulating layer 128 covering the driving gate electrode 133 is formed on the gate insulating layer 127. A contact hole 128a exposing the source region 134 and the drain region 136 of the driving semiconductor layer 137 is formed in the gate insulating layer 127 and the interlayer insulating layer 128.

The interlayer insulating layer 128 may be formed by using a ceramic material such as, for example, silicon nitride (SiNₓ) or silicon oxide (SiO₂), like the gate insulating layer 127.

In addition, a data line including a driving source electrode 131 and a driving drain electrode 132 is formed on the interlayer insulating layer 128. Further, the driving source electrode 131 and the driving drain electrode 132 are connected with the source region 134 and the drain region 136 of the driving semiconductor layer 137 through the contact holes 128a formed in the interlayer insulating layer 128 and the gate insulating layer 127, respectively.

As such, the driving thin film transistor 130 including the driving semiconductor layer 137, the driving gate electrode 133, the driving source electrode 131, and the driving drain electrode 132, is formed. The configuration of the driving thin film transistor 130 is not limited to the aforementioned example, and may be variously modified as a known configuration which may be easily implemented by those skilled in the art.

According to one embodiment, the thin film transistor is formed on the display area of the substrate 123.

In addition, a planarization layer 124 covering the data line is formed on the interlayer insulating layer 128. The planarization layer 124 serves to remove and planarize a step in order to increase emission efficiency of the organic light emitting element to be formed thereon.

Embodiments are not limited to the aforementioned structure, and in some cases, one of the planarization layer 124 and the interlayer insulating layer 128 may be omitted.

The planarization layer 124 may include polyacrylates resin, epoxy resin, phenolic resin, polyamides resin, polyimide resin, unsaturated polyester resin, poly phenylenethers resin, poly phenylenesulfides resin, or benzocyclobutene (BCB).

The planarization layer 124 may cover the driving source and drain electrodes 131 and 132 described above. The planarization layer 124 has an electrode via hole 122a exposing a part of the drain electrode 132.

In addition, a first electrode, or a pixel electrode 160 is formed on the planarization layer 124 of the display area DA. The organic light emitting diode display includes a plurality of pixel electrodes 160, each of which is disposed for each of the plurality of pixels. The pixel electrodes 160 are spaced apart from each other.

The pixel electrode 160 is connected to the drain electrode 132 through the electrode via hole 122a of the planarization layer 124.

Further, a pixel defining layer 125 having an opening exposing the pixel electrode 160 is formed on the planarization layer 124. The pixel defining layer 125 has a plurality of openings formed for each pixel.

The organic emission layer 170 may be formed for each opening formed by the pixel defining layer 125. Accordingly, a pixel area in which each organic emission layer is formed by the pixel defining layer 125 may be defined.

The pixel electrode 160 is disposed to correspond to the opening of the pixel defining layer 125. However, the pixel electrode 160 is not necessarily disposed only in the opening of the pixel defining layer 125, but may be disposed below the pixel defining layer 125 so that a part of the pixel electrode 160 overlaps with the pixel defining layer 125.

The pixel defining layer 125 may include resins such as, for example, polyacrylates resin and polyimides resin or silica-series inorganic materials.

The organic emission layer 170 is formed on the pixel electrode 160.

The organic emission layer 170 is formed in a multilayer including one or more of an emission layer, a hole-injection layer (HIL), a hole-transporting layer (HTL), an electron-transporting layer (ETL), and an electron-injection layer (EIL).

When the organic emission layer 170 includes all of the layers, the HIL is positioned on the pixel electrode 160 which is an anode, and the HTL, the emission layer, the ETL, and the EIL may be sequentially laminated thereon.

The organic emission layer 170 may include, for example, a red organic emission layer emitting red light, a green organic emission layer emitting green light, and a blue organic emission layer emitting blue light. The red organic emission layer, the green organic emission layer, and the blue organic emission layer are formed in a red pixel, a green pixel, and a blue pixel, respectively, thereby implementing a color image.

Further, in the organic emission layer 170, all of the red organic emission layer, the green organic emission layer, and the blue organic emission layer are together laminated on the red pixel, the green pixel, and the blue pixel, and a red color filter, a green color filter, and a blue color filter are formed for each pixel, thereby implementing a color image.

As another example, white organic emission layers emitting white light are formed in all of the red pixel, the green pixel, and the blue pixel, and a red color filter, a green color filter, and a blue color filter are formed for each pixel, thereby implementing the color image. In the case of implementing the color image by using the white organic emission layer and the white color filter, a deposition mask for depositing the red organic emission layer, the green organic emission layer, and the blue organic emission layer on respective subpixels, that is, the red subpixel, the green subpixel, and the blue subpixel does not need to be used.

In another example, the white organic emission layer may be formed by one organic emission layer, and also includes a configuration formed so as to emit white light by laminating a plurality of organic emission layers. For example, the white organic emission layer may include a configuration which may emit white light by combining at least one yellow organic emission layer and at least one blue organic emission layer, a configuration which may emit white light by combining at least one cyan organic emission layer and at least one red organic emission layer, a configuration which may emit white light by combining at least one magenta organic emission layer and at least one green organic emission layer, and the like.

In addition, a second electrode, or a common electrode 180 may be formed on the organic emission layer 170. As such, the organic light emitting element LD including the pixel electrode 160, the organic emission layer 170, and the common electrode 180 is formed.

Each of the pixel electrode 160 and the common electrode 180 may include a transparent conductive material or a transflective or reflective conductive material. For example, the pixel electrode 160 and the common electrode 180 may include a transparent conductive material such as, for example, indium tin oxide (ITO), indium zinc oxide (IZO), zinc oxide (ZnO), or indium oxide (In₂O₃), or a reflective metal such as, for example, lithium (Li), calcium (Ca), lithium fluoride/calcium (LiF/Ca), lithium fluoride/aluminum (LiF/Al), aluminum (Al), silver (Ag), magnesium (Mg), or gold (Au).

According to a kind of material forming the pixel electrode 160 and the common electrode 180, the organic light emitting diode display may be a top emission type, a bottom emission type, or a double-sided emission type.

According to embodiments, the passivation layer 400 covering the common electrode 180 may be formed on the common electrode 180. The passivation layer 400 covers the entire common electrode 180 in the display area DA to protect the common electrode 180. The passivation layer 400 may prevent a filler 700, described below, from directly contacting the common electrode 180 and the pixel defining layer 125.

In the non-display area NDA, the passivation layer 400 covers both the common electrode 180 and the pixel defining layer 125. As illustrated in FIG. 2, in an area where the common electrode 180 does not overlap with the getter 300, when the passivation layer 400 does not exist, a part of the pixel defining layer 125 is exposed. As a result, the pixel defining layer 125 and the filler 700 directly contact each other. When the pixel defining layer 125 and the filler 700 directly contact each other, some organic components configuring the filler 700 penetrate into the pixel defining layer 125 to deteriorate the organic emission layer, thereby causing a pixel reduction phenomenon.

According to embodiments, in the non-display area NDA, the passivation layer 400 covers the pixel defining layer 125 and the common electrode 180, and may overlap with the getter 300. The passivation layer 400 may be positioned below the getter 300 so as to partially overlap with the getter 300. As a result, the passivation layer 400 may prevent the pixel defining layer 125 and the filler 700 from contacting each other. Therefore, the passivation layer 400 may prevent the organic emission layer from deteriorating due to the organic components included in the filler 700.

The passivation layer 400 may be configured by a plurality of layers. Further, the passivation layer 400 may include an organic material or an inorganic material. The organic material or the inorganic material is coated and cured on the pixel defining layer 125 and the common electrode 180 to form the passivation layer 400.

The inorganic material configuring the passivation layer 400 may be one of, for example, silicon nitride (SiNx), silicon oxide (SiOx), SiOC, or SiC.

When the passivation layer 400 includes the organic material, the passivation layer 400 overlaps with a part of the getter 300. In this case, the passivation layer 400 overlaps with the entire getter 300 or is disposed so as not to pass through the getter 300.

Further, when passivation layer 400 includes the inorganic material, the passivation layer 400 may partially overlap with the getter 300 or entirely overlap with the getter 300 to pass through the getter 300. In this case, the passivation layer 400 may be extended to the encapsulation part 500 by passing through the getter 300 to overlap with the encapsulation part 500.

The filler 700 may be formed on the passivation layer 400. The filler 700 absorbs external impact and may uniformly maintain a distance between the encapsulation substrate (not illustrated) and the substrate 123. The filler 700 may include a material having high transmittance. For example, the filler 700 may include epoxy, polyimide, urethane acrylate, epoxy acrylate or silicones (e.g., bisphenol A type epoxy, cycloaliphatic epoxy resin, phenyl silicone resin or rubber, acrylic epoxy resin, aliphatic urethane acrylate, and the like)—based resins.

The encapsulation substrate (not illustrated) is positioned on the filler 700. The encapsulation substrate (not illustrated) protects the organic light emitting element and the like positioned in the display area DA from external moisture or oxygen together with the encapsulation part 500 and the getter 300. The encapsulation substrate (not illustrated) may include a glass material or a plastic material. In some cases, a polarization film or a color conversion layer may be further provided on the encapsulation substrate (not illustrated).

Referring to FIG. 3, at one side of the non-display area NDA, the common electrode 180 is connected to a common voltage line 210. The common electrode 180 may receive common voltage from the common voltage line 210. The common electrode 180 is connected with the common voltage line 210 through a contact hole formed in the pixel defining layer 125 and the planarization layer 124. In this case, the passivation layer 400 may cover the common electrode 180 in the area. In the area where the common electrode 180 and the common voltage line 210 contact each other, the common electrode 180 may fully cover the pixel defining layer 125 unlike the area where the getter 300 is formed. The passivation layer 400 may be covered by the filler 700.

Hereinafter, one pixel of the organic light emitting element formed in the display area DA will be described with reference to FIG. 4.

FIG. 4 is a layout view of one pixel of the organic light emitting diode display.

Referring to FIG. 4, the organic light emitting diode display includes a plurality of signal lines 121, 171, and 172, and a pixel PX connected thereto. The pixel PX may be one of a red pixel R, a green pixel G, or a blue pixel B.

The signal lines includes a gate line 121 transferring a scanning signal, a data line 171 transferring a data signal, a driving voltage line 172 transferring driving voltage, and the like.

The gate lines 121 extend substantially in a row direction and are substantially parallel to each other, and the data lines 171 extend substantially in a column direction and are substantially parallel to each other. The driving voltage lines 172 extend substantially in a column direction, but may extend in a row direction or be formed in a matrix.

One pixel PX includes a thin film transistor including a switching transistor T1 and a driving transistor T2, a storage capacitor Cst, and an organic light emitting element LD. Although not illustrated, one pixel PX may further include a thin film transistor and a capacitor in order to compensate for current provided in the organic light emitting element.

A switching transistor T1 includes a control terminal N1, an input terminal N2, and an output terminal N3. The control terminal N1 is connected to the gate line 121, the input terminal N2 is connected to the data line 171, and the output terminal N3 is connected to the driving transistor T2.

The switching transistor T1 transfers a data signal received from the data line 171 to the driving transistor T2 in response to a scanning signal received from the gate line 121.

In addition, the driving transistor T2 also includes the control terminal N3, an input terminal N4, and an output terminal N5. The control terminal N3 is connected to the switching transistor T1, the input terminal N4 is connected to the driving voltage line 172, and the output terminal N5 is connected to the organic light emitting element LD.

The driving transistor T2 runs output current Id of which amplitude varies according to a voltage applied between the control terminal N3 and the output terminal N5.

The capacitor Cst is connected between the control terminal N3 and the input terminal N4 of the driving transistor T2. The capacitor Cst charges the data signal applied to the control terminal N3 of the driving transistor T2, and maintains the charged data signal even after the switching transistor T1 is turned off.

The organic light emitting element LD, for example, as an organic light emitting diode (OLED), has an anode connected to the output terminal N5 of the driving transistor T2 and a cathode connected to a common voltage ELVSS. The organic light emitting element LD emits light by varying intensities according to the output current Id of the driving transistor T2 to display an image.

The organic light emitting element LD may include an organic material which uniquely emits one or more of the primary colors such as, for example, three primary colors of red, green, and blue, and the organic light emitting diode display displays a desired image by a spatial sum of the colors.

The switching transistor T1 and the driving transistor T2 are n-channel field effect transistors (FET), but at least one thereof may be a p-channel field effect transistor. Further, a connection relationship among the transistors T1 and T2, the capacitor Cst, and the organic light emitting element LD may be changed in other embodiments.

According to embodiments, the passivation layer 400 is disposed to cover the pixel defining layer 125 and the common electrode 180, and to overlap with the getter 300 to prevent the filler 700 and the pixel defining layer 125 from directly contacting each other, and as a result, it is possible to prevent the organic emission layer from deteriorating due to the organic components configuring the filler 700.

While this invention has been described in connection with certain embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode display, comprising:
a substrate including a display area displaying an image and a non-display area positioned around the display area;
a first electrode formed in the display area connected with a thin film transistor;
a pixel defining layer formed on the first electrode thereby defining a pixel area;
an organic emission layer formed on the first electrode contacting the first electrode in the pixel area;
a second electrode formed on the pixel defining layer contacting the organic emission layer;
a passivation layer formed on the second electrode and the pixel defining layer;
a filler covering the passivation layer in the display area; and
a getter formed in the non-display area on the substrate and surrounding the display area,
wherein the passivation layer overlaps with at least a part of the getter.

2. The organic light emitting diode display of claim 1, wherein:
the passivation layer contacts the second electrode and the pixel defining layer.

3. The organic light emitting diode display of claim 1, wherein:
the passivation layer includes an organic material.

4. The organic light emitting diode display of claim 1, wherein:
the passivation layer includes an inorganic material.

5. The organic light emitting diode display of claim 4, wherein:
the inorganic material includes at least one of silicon nitride (SiNx) or silicon oxide (SiOx).

6. The organic light emitting diode display of claim 1, wherein:
the passivation layer includes a plurality of layers. The organic light emitting diode display of claim 1, wherein:
the filler includes at least one of epoxy, epoxy acrylate, polyimide, or silicon.

8. The organic light emitting diode display of claim 1, wherein:
the thin film transistor includes:
an active layer formed on the substrate;
a gate electrode formed on the active layer; and
source and drain electrodes positioned on the gate electrode and connected with the active layer.

9. The organic light emitting diode display of claim 1, further comprising:
an encapsulation part surrounding the getter in the non-display area.

10. The organic light emitting diode display of claim 9, wherein:
the passivation layer overlaps with a part of the encapsulation part.

11. The organic light emitting diode display of claim 10, wherein:
the passivation layer includes an inorganic material.

12. The organic light emitting diode display of claim 11, wherein:
the inorganic material includes at least one ofsilicon nitride (SiNx) or silicon oxide (SiOx).

13. The organic light emitting diode display of claim 9, further comprising:
an encapsulation substrate disposed to face the substrate on filler and contacting the encapsulation part.

14. A method of manufacturing the organic light emitting diode display of claim 1, the method comprising:
providing a substrate including a display area displaying an image and a non-display area positioned around the display area;
forming a first electrode in the display area on the substrate and connected with a thin film transistor;
forming a pixel defining layer on the first electrode thereby defining a pixel area;
forming an organic emission layer on the first electrode and contacting the first electrode in the pixel area;
forming a second electrode on the pixel defining layer and contacting the organic emission layer;
forming a passivation layer on the second electrode and the pixel defining layer;
covering the passivation layer in the display area by a filler; and
forming a getter in the non-display area on the substrate and surrounding the display area, wherein the passivation layer overlaps with the getter.

15. The method of claim 14, wherein:
the passivation layer contacts the second electrode and the pixel defining layer.

16. The method of claim 14, wherein:
the passivation layer includes a plurality of layers.

17. The method of claim 14, wherein:
the filler includes at least one of epoxy, epoxy acrylate, polyimide, or silicon.

18. The method of claim 14, wherein:
the thin film transistor includes:
an active layer formed on the substrate;
a gate electrode formed on the active layer; and
source and drain electrodes positioned on the gate electrode and connected with the active layer.

19. The method of claim 14, further comprising:
an encapsulation part surrounding the getter in the non-display area, wherein the passivation layer overlaps with a part of the encapsulation part.

20. The method of claim 19, further comprising:
an encapsulation substrate disposed to face the substrate on filler and contacting the encapsulation part.
